(19) United States
(12) Patent Application Publication
(10) Pub. No.: US 2026/0024573 A1
(43) Pub. Date: Jan. 22, 2026

(54) RANDOM ACCESS MEMORY INCLUDING HYBRID CHANNEL MATERIAL AND METHOD FOR MANUFACTURING THE SAME

(71) Applicant: SEOUL NATIONAL UNIVERSITY R&DB FOUNDATION, Seoul (KR)

(72) Inventors: Jae-Joon KIM, Seoul (KR); Munhyeon KIM, Seoul (KR)

(21) Appl. No.: 19/265,632

(22) Filed: Jul. 10, 2025

(30) Foreign Application Priority Data
Jul. 17, 2024 (KR) 10-2024-0094261
Jun. 16, 2025 (KR) 10-2025-0078463

(51) Int. Cl. G11C 11/409

(52) U.S. Cl. CPC G11C 11/409

(57) ABSTRACT

A random access memory according to one embodiment comprises: a first transistor having a channel formed of IGZO (Indium Gallium Zinc Oxide) material; second and third transistors having channels respectively formed of silicon material and connected in series; and a storage node, defined at a node where one terminal of the first transistor and a gate terminal of the second transistor are connected, in which data is stored.

### CROSS-REFERENCE TO RELATED APPLICATION

This application claims the benefit under 35 USC 119 (a) of Korean Patent Application Nos. 10-2025-0078463 filed on Jun. 16, 2025 and 10-2024-0094261 filed on Jul. 17, 2024 in the Korean Intellectual Property Office, the entire disclosures of which are incorporated herein by reference for all purposes.

### BACKGROUND

The present invention relates to a random access memory including a hybrid channel material and a method of manufacturing the same.

### SUMMARY

Conventional semiconductor memory devices are classified into SRAM used as cache memory and DRAM used as main memory. SRAM is used for high-speed operation, but generally, one memory cell includes at least six transistors, resulting in low integration density and thus requiring a large area for high-capacity memory implementation. DRAM typically has a 1T1C cell structure in which one memory cell includes one transistor and one capacitor, allowing for high integration and high-capacity implementation. However, compared to SRAM, DRAM has slower operating speed and shorter retention time, requiring periodic refresh cycles even during periods when no read/write operations are performed.

The present invention proposes a new structure of random access memory that can replace such SRAM and DRAM. That is, the present invention provides a random access memory that is composed of a smaller number of elements compared to SRAM to achieve high integration, provides fast operation speed, and also increases the data retention time compared to DRAM. In addition, the present invention proposes a random access memory capable of improving the variability of memory cells, which is represented by the threshold voltage distribution characteristics of the cells.

Meanwhile, the present invention proposes a random access memory capable of performing MAC (multiply and accumulation) operations as a core function of CIM (Compute-in-Memory), which enables computation within the memory.

To this end, the present invention proposes a hybrid-structured random access memory combining a CMOS-based transistor using a silicon channel material and a transistor in which the channel is formed with an IGZO (Indium Gallium Zinc Oxide) material.

### PRIOR ART DOCUMENT

Korean Unexamined Patent Publication No. 10-2021-0096678 (Title of the Invention: Memory device having shared read/write data lines for 2-transistor vertical memory cells)

The present invention aims to solve the problems of the aforementioned conventional technologies, and its objective is to propose a new structure of random access memory and a method for manufacturing the same using a transistor having a channel formed of a silicon-based material and a transistor having a channel formed of an IGZO (Indium Gallium Zinc Oxide) material.

However, the technical problem to be solved by the present embodiment is not limited to the aforementioned objectives, and other technical problems may also exist.

As a technical means for achieving the above-mentioned objectives, a random access memory according to a first aspect of the present invention comprises: a first transistor having a channel formed of IGZO (Indium Gallium Zinc Oxide) material; a second and a third transistor, each having a channel formed of a silicon material and connected in series; and a storage node, defined at a node where one terminal of the first transistor and the gate terminal of the second transistor are connected, in which data is stored.

According to the configuration of the present invention, by employing a structure that combines silicon-based transistors and IGZO-based transistors, it is possible to increase the retention time of the memory cell. This enables the maintenance of data corresponding to weights, thereby allowing for CIM (Compute-in-Memory) operations such as MAC (Multiply and Accumulation) operations.

In addition, according to the present invention, the variability (threshold voltage variation) of memory cells can be reduced. During CIM operations, activation data is applied simultaneously to all word lines (WLs) of the memory cell array, which may cause the variability to accumulate in the partial sums. Since the bit resolution and margin of sensing circuits such as ADCs (Analog-to-Digital Converters) are limited for area and energy efficiency, minimizing the variability of memory cells is essential to ensure successful CIM operations. Since some of the memory cells in the present invention use CMOS transistors with silicon channels, such variability can be minimized. Furthermore, the linearity of MAC operation results can also be improved.

### BRIEF DESCRIPTION OF THE DRAWINGS

FIG. 1 is a diagram illustrating the basic structure of a random access memory according to an embodiment of the present invention.

FIG. 2 is a perspective view illustrating an implementation example of the random access memory according to an embodiment of the present invention.

FIG. 3 is a plan view illustrating an implementation example of the random access memory according to an embodiment of the present invention, shown layer by layer.

FIG. 4 is a diagram illustrating the random access memory according to an embodiment of the present invention arranged in an array form.

FIGS. 5 and 6 are diagrams for explaining the operation of the random access memory according to an embodiment of the present invention.

FIGS. 7 and 8 are diagrams for explaining the CIM (Compute-in-Memory) operation of the random access memory according to an embodiment of the present invention.

### DETAILED DESCRIPTION

Hereinafter, exemplary embodiments of the present invention will be described in detail with reference to the accompanying drawings so that those skilled in the art can easily implement the invention. However, the present invention may be embodied in various different forms and is not limited to the embodiments described herein. In the drawings, parts irrelevant to the explanation are omitted to clearly describe the invention, and similar reference numerals denote similar elements throughout the specification.

Throughout the specification, when a certain part is described as being “connected” to another part, this includes not only being “directly connected” but also “electrically connected” with another element interposed therebetween. Also, when a certain part is said to “include” a component, unless stated otherwise, it does not exclude the presence of other components and may further include additional components.

Throughout this specification, when a component is described as being “on” another component, this includes not only a case where the component is in contact with the other component but also a case where another component is interposed between the two components.

Hereinafter, preferred embodiments of the present invention will be described in detail with reference to the accompanying drawings and the descriptions below. However, the present invention is not limited to the embodiments described herein and may be embodied in other forms. The same reference numerals denote the same components throughout the entire specification.

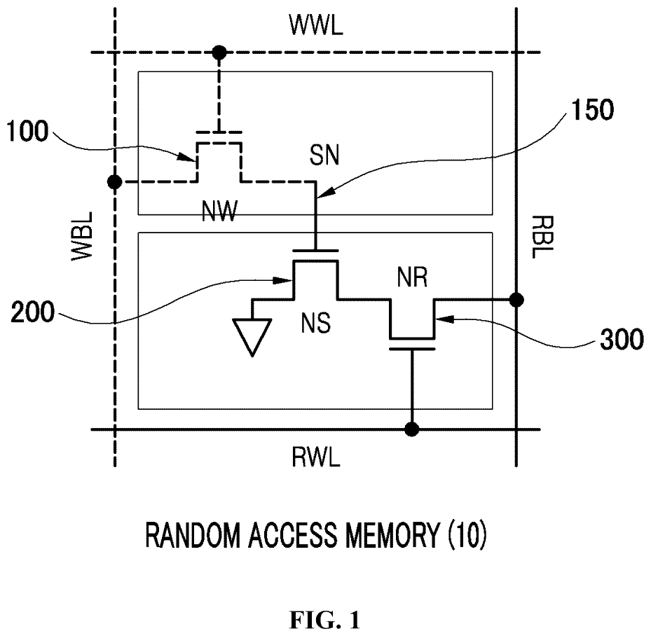

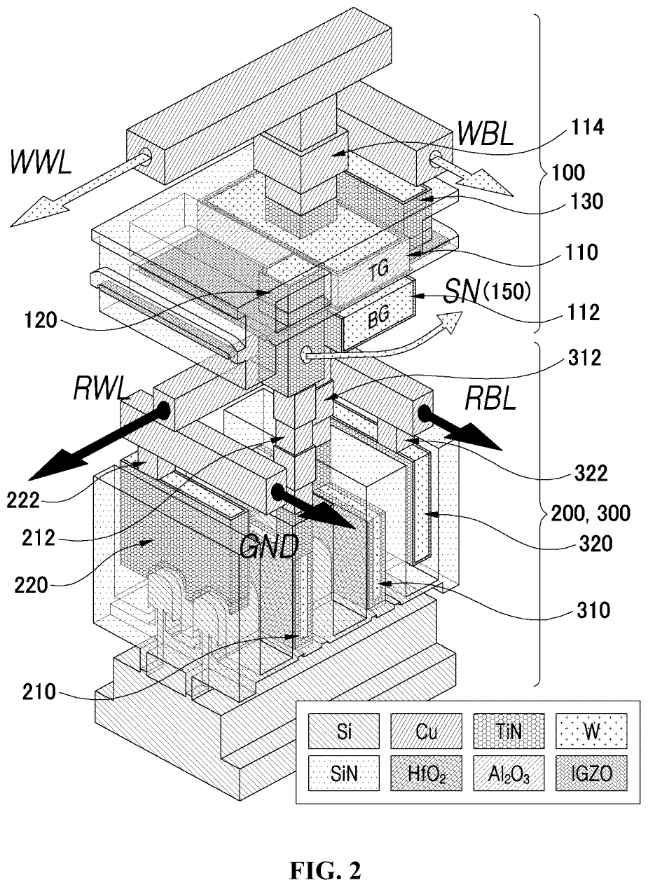

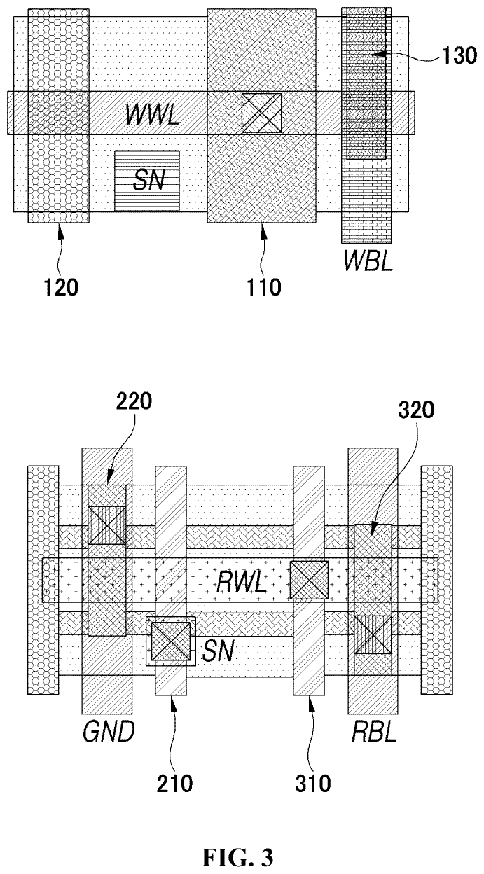

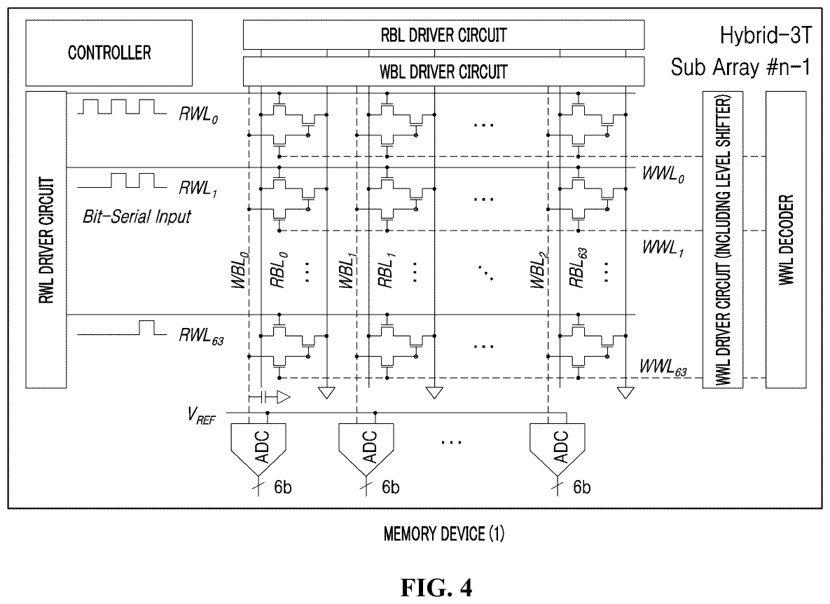

FIG. 1 is a diagram showing the basic structure of a random access memory according to an embodiment of the present invention, FIG. 2 is a perspective view showing an implementation example of the random access memory according to an embodiment of the present invention, FIG. 3 is a plan view showing the implementation example of the random access memory according to an embodiment of the present invention by layer, and FIG. 4 illustrates the random access memory according to an embodiment of the present invention arranged in an array form.

As shown, the random access memory (10) according to the present invention includes a first transistor (100) having a channel formed of IGZO (Indium Gallium Zinc Oxide) material; second and third transistors (200, 300) having channels formed of silicon material and connected in series; and a data storage node (150, SN) defined at a node where one terminal of the first transistor (100) and the gate terminal of the second transistor (200) are connected, and where data is stored. In this manner, the present invention is characterized by a hybrid structure in which the channel materials of the first transistor (100) and the second and third transistors (200, 300) are applied differently. The first transistor (100) operates as a write transistor for writing data to the storage node (150), and the second and third transistors (200, 300) can operate as read transistors for reading the state of the storage node.

In addition, a write word line (WWL) may be connected to the gate of the first transistor (100), and a write bit line (WBL) may be connected to its other terminal. A read word line (RWL) may be connected to the gate of the third transistor (300), and a read bit line (RBL) may be connected to its other terminal. One terminal of the second transistor (200) may be grounded, and the other terminal of the second transistor (200) may be connected to one terminal of the third transistor (300).

The write word line (WWL) and write bit line (WBL) may each extend in a direction that intersects perpendicularly. Likewise, the read word line (RWL) and read bit line (RBL) may also each extend in a perpendicularly intersecting manner. Furthermore, the write word line (WWL) and the read word line (RWL) may extend in mutually parallel directions, and the write bit line (WBL) and the read bit line (RBL) may also extend in mutually parallel directions.

Each transistor may be a field-effect transistor (FET) including a gate, drain, and source, and the channel material of each transistor (100, 200, 300) may be set differently. In particular, the second and third transistors (200, 300) are conventional CMOS-based transistors using silicon material as the channel.

As shown in FIG. 2, the random access memory (10) is formed in a three-dimensional structure, where the first transistor (100) is formed on an upper layer and the second and third transistors (200, 300) are formed on a lower layer.

The first transistor (100) may include a first gate (110, 112), a first gate contact (114), a first drain (120), and a first source (130). The first gate contact (114) connects the first gate (110, 112) with the write word line (WWL). The drain (120) is connected to the storage node (150), and the source (130) is connected to the write bit line (WBL). Although the first gate (110, 112) of the first transistor (100) is illustrated as having a structure that includes both a back gate (BG) and a top gate (TG), this is merely exemplary, and it is also possible to implement it in the form of a single gate.

Additionally, the second transistor (200) and the third transistor (300), formed on the lower layer, may be implemented in a FinFET structure, in which the channels are shaped like fins and arranged in parallel. However, this is merely exemplary, and the structure may alternatively be implemented in forms such as GAA-FET, NS-FET, or NC-FET.

The second transistor (200) may include a second gate (210), a second drain (220) connected to ground (GND), and a second source (not shown). The third transistor (300) may include a third gate (310), a third drain (320) connected to a read bit line (RBL), and a third source (not shown). In this case, the second gate (210) and the third gate (310), as well as the second drain (220) and the third drain (320), may all extend in parallel directions. In particular, the second gate (210) and the third gate (310), and the second drain (220) and the third drain (320), may extend in directions parallel to the direction in which the read bit line (RBL) or ground extends. Furthermore, a gate contact (212) connected to the second gate (210) is connected to the storage node (150) formed on the upper layer. Additionally, a gate contact (312) connected to the third gate (310) is connected to the read word line (RWL) formed on the lower layer.

The upper part of FIG. 3 illustrates a cross-sectional view of the first transistor (100) formed on the upper layer, showing the formation of the first gate (110), first drain (120), and first source (130), as well as the connection between the storage node (SN) and the write bit line (WBL).

Additionally, the lower part of FIG. 3 illustrates a cross-sectional view of the second transistor (200) and third transistor (300) formed on the lower layer, showing the formation of the second gate (210), second drain (220), third gate (310), and third drain (320), as well as the connection between the ground line (GND) and the read bit line (RBL).

Referring to FIG. 4, each random access memory (10) may be arranged in an array form, in which a plurality of write word lines (WWL) and a plurality of read word lines (RWL) extend horizontally in parallel with each other, and a plurality of write bit lines (WBL) and a plurality of read bit lines (RBL) extend vertically in parallel with each other for each random access memory (10).

Also referring to FIG. 4, the memory device (1), in which multiple random access memories (10) are arranged, may include a controller, RBL driving circuit, WBL driving circuit, RWL driving circuit, WWL driving circuit, and a plurality of ADCs (Analog-to-Digital Converters) for operating the random access memories (10).

The memory device (1) of the present invention has the characteristics of eDRAM, and since the channel materials of the first transistor (100) and the third transistor (300) are different, the circuits that drive each transistor—i.e., the WWL driving circuit and the RWL driving circuit—are configured separately. Furthermore, in order to drive the third transistor (300), which includes a silicon-based channel material and has a monolithic 3D structure, the WWL driving circuit may include a level shifter. Preferably, this level shifter is placed between the WWL decoder and the memory array.

Since the first transistor (100) is based on IGZO, it requires a higher word line driving voltage (e.g., VWWL=2 V) than the supply voltage of the third transistor (300) (e.g., VDD=1 V). To achieve this voltage boost for the word line, the level shifter is combined with the WWL driving circuit. Through this approach, the transistors included in the controller and WWL decoder can be designed with thin oxide films, thereby improving area and energy efficiency.

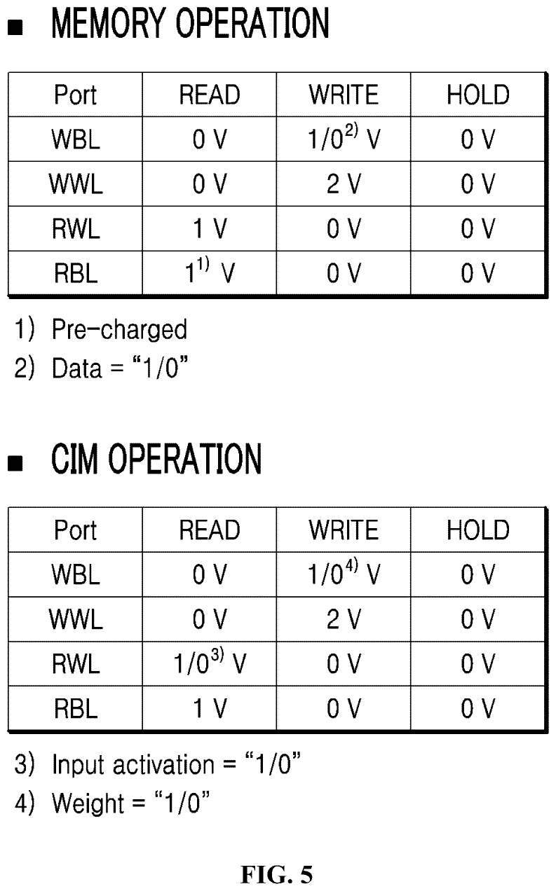

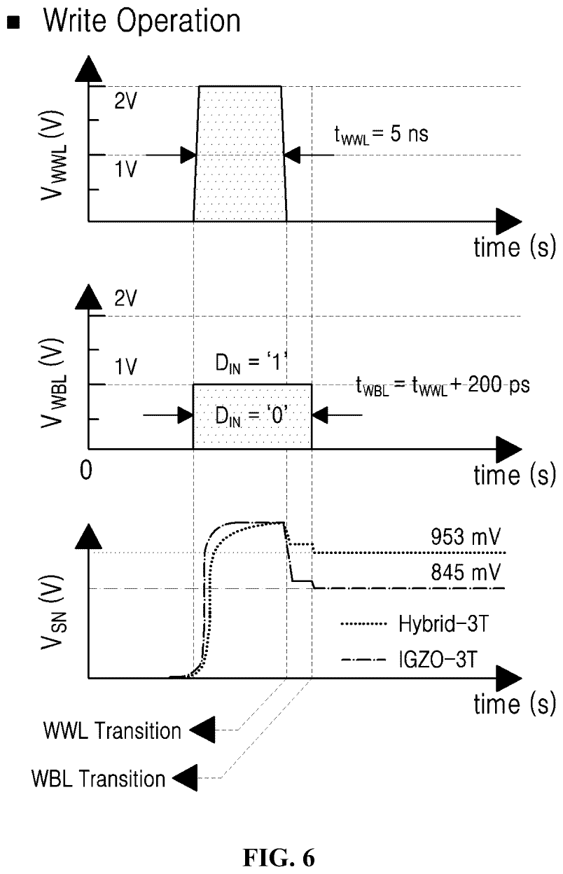

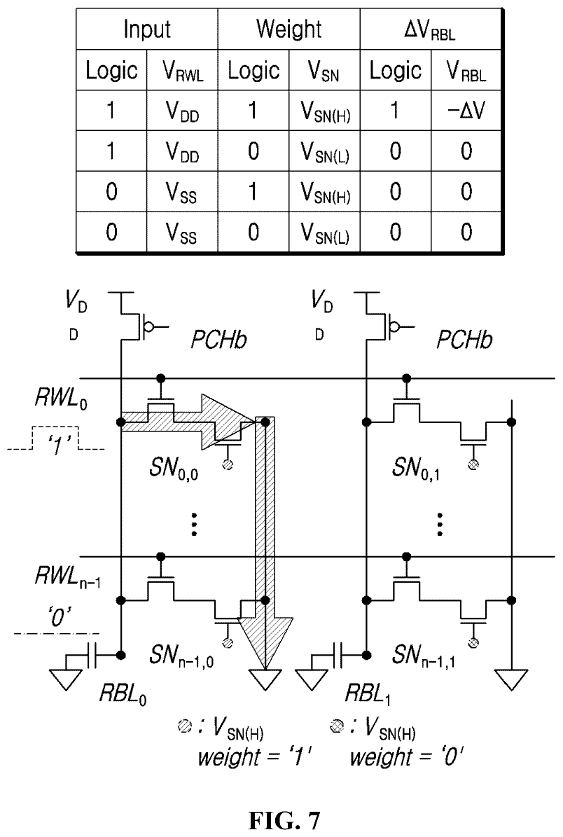

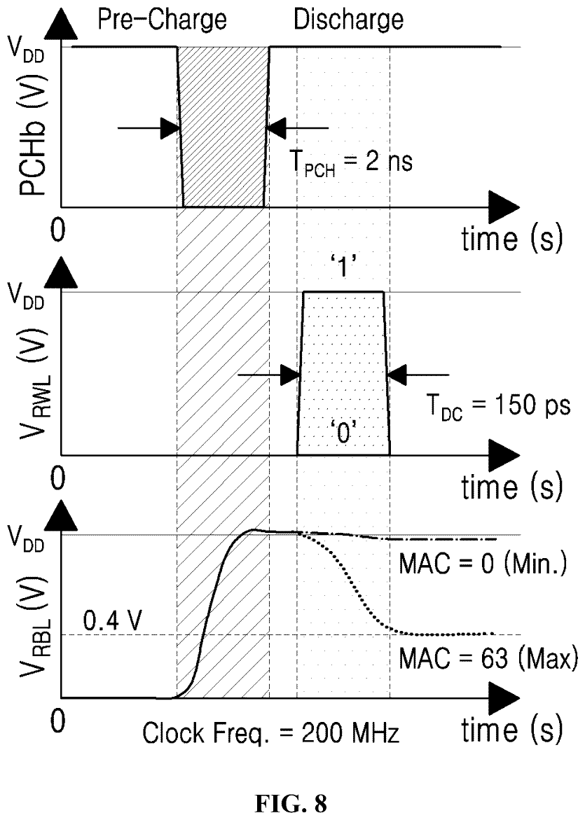

FIGS. 5 and 6 are diagrams for explaining the operation of the random access memory according to an embodiment of the present invention, and FIGS. 7 and 8 are diagrams for explaining the CIM (Compute-In-Memory) operation of the random access memory according to an embodiment of the present invention.

The random access memory (10) can fundamentally perform data write and read operations, and it can also perform CIM operations such as MAC (multiply and accumulate) operations.

First, regarding the data read operation, the voltages of the write word line (WWL) and the write bit line (WBL) are fixed at 0. The read bit line (RBL) of the target random access memory (10) is precharged to a high-level voltage, and a high or low voltage is applied to the read word line (RWL) of the random access memory (10) depending on whether the corresponding cell is the read target. That is, a high-level voltage is applied to the read word line (RWL) of the read-target random access memory (10), turning on the third transistor (300). Accordingly, if the storage node (SN) holds a high-level voltage, the second transistor (200) is turned on, and the read bit line (RBL) is connected to ground through the turned-on second transistor (200) and third transistor (300). As a result, the precharged high-level voltage of the read bit line (RBL) is discharged to a low level. However, if the storage node (SN) holds a low-level voltage, the second transistor (200) remains turned off, and the read bit line (RBL) maintains its precharged high-level state.

Next, in the data write operation, the voltages of the read word line (RWL) and the read bit line (RBL) are fixed at 0, so the third transistor (300) is turned off. In this state, the write word line (WWL) of the write-target random access memory (10) is fixed to a high-level voltage (e.g., 2 V) to turn on the first transistor (100). Then, write data (0 or 1) is applied to the write bit line (WBL) of the random access memory (10). If the write data is a high-level data (1), a high-level voltage is stored in the storage node (SN) via the first transistor (100); if the write data is a low-level data (0), a low-level voltage is stored in the storage node (SN) via the first transistor (100).

As shown in FIG. 6, as described above, the high-level voltage applied to the write word line (WWL) is set to a high value, such as 2 V. Additionally, the duration for which the data (i.e., high-level or low-level voltage) is applied to the write bit line (WBL) can be set to be slightly longer than the duration for which the high-level voltage is applied to the write word line (WWL). Meanwhile, it can be confirmed that the high-level voltage at the storage node of the hybrid-structured random access memory (10) according to the present invention is maintained at a higher level compared to that of a conventional IGZO-structured random access memory. This is because the use of the hybrid structure increases the gate capacitance of the second transistor (200).

During the hold operation, all word lines (WWL, RWL) and bit lines (WBL, RBL) are maintained at 0.

Next, the CIM (Compute-In-Memory) operation will be described.

A multiplication operation can be performed such that the value stored in the storage node (SN) of each random access memory serves as a weight, and input data (activation) is applied via the read word line (RWL).

First, the operation of storing the weight data into the storage node (SN) is the same as the write operation described above. That is, with the read word line (RWL) and the read bit line (RBL) fixed at 0 V, the write word line (WWL) of the target random access memory (10) is fixed at a high-level voltage, and the write bit line (WBL) of the random access memory (10) is supplied with the write data (0 or 1). Through this, the weight data can be stored in the storage node (SN) in advance.

Next, to apply input data, the write word line (WWL) and the write bit line (WBL) are fixed at 0 V, turning off the first transistor (100). Then, the read bit line (RBL) is pre-charged to a high-level voltage, and a high-level or low-level voltage is applied to the read word line (RWL) of the random access memory (100) targeted for CIM computation, depending on the input data. To pre-charge the read bit line (RBL), as shown in FIG. 7, a precharge transistor may be further included, which selectively connects the power supply (VDD) and each read bit line (RBL) based on a precharge signal (PCHb).

According to this configuration, only when the value stored in the storage node (SN) of each random access memory (10) is high-level data (1) and the input data is also high-level data (1), both the second transistor (200) and the third transistor (300) are turned on, and the read bit line (RBL), which was pre-charged to a high level, is discharged to ground. In other cases, since at least one of the second transistor (200) or third transistor (300) remains turned off, the read bit line (RBL) is not discharged.

Accordingly, as shown in the table of FIG. 7, it can be confirmed that an AND operation is performed between the input data and the weight data.

As shown in FIG. 8, when a low-level precharge signal (PCHb) is momentarily applied, the read bit line (RBL) is precharged to a high level. Subsequently, depending on the data applied to the read word line (RWL), it can be observed that the voltage of the read bit line (RBL) varies. For example, when 64 random access memory (10) cells are connected in parallel to a single read bit line (RBL), and the weight data and input data of each random access memory (10) are both ‘1’, then all of the second transistors (200) and third transistors (300) in the 64 random access memory cells (10) are turned on. As a result, the read bit line (RBL), which was precharged to a high level, is discharged, and the voltage (VRBL) of the read bit line (RBL) reaches a minimum value. Because of this structure, depending on whether the weight data and input data of each random access memory (10) are both ‘1’, the discharge behavior of the read bit line (RBL) varies. Therefore, by measuring the voltage (VRBL) of the read bit line (RBL), the summation result of the multiplication operations (i.e., the MAC operation result) across the 64 random access memory cells (10) can be determined. If the read bit line (RBL) remains at the high-level state, it confirms that the MAC operation result is ‘0’.

According to the structure of the present invention, improvements can also be observed in terms of cell operation. Compared to conventional DRAM structures, it demonstrates superior operating speed and, due to the extended retention time, enables energy-efficient high-speed operation.

The above description of the present invention is intended as an example, and it will be understood by those skilled in the art that various modifications can be made without departing from the spirit or essential characteristics of the invention. Therefore, the embodiments described above should be regarded as illustrative in every respect and not as restrictive. For instance, each component described as a single entity may be implemented in a distributed manner, and likewise, components described as distributed may also be implemented in a combined form.

The scope of the present invention is defined not by the foregoing detailed description but by the following claims, and all modifications or alterations derived from the meanings, scope, and equivalents of the claims should be interpreted as falling within the scope of the present invention.

### BRIEF DESCRIPTION OF THE REFERENCE NUMERALS

10: Random Access Memory
100: First Transistor
200: Second Transistor
300: Third Transistor

What is claimed is:

1. A random access memory comprising:
a first transistor having a channel formed of IGZO (Indium Gallium Zinc Oxide) material;
second and third transistors, each having a channel formed of silicon material and connected in series; and
a storage node, defined at a node where one terminal of the first transistor and a gate terminal of the second transistor are connected, in which data is stored.

2. The random access memory of claim 1,
wherein the first transistor operates as a write transistor for writing data to the storage node, and
the second and third transistors operate as read transistors for reading the state of the storage node.

3. The random access memory of claim 1,
wherein the first transistor has a write word line (WWL) connected to its gate and a write bit line (WBL) connected to its other terminal,
the third transistor has a read word line (RWL) connected to its gate and a read bit line (RBL) connected to its other terminal,
one terminal of the second transistor is grounded, and
the other terminal of the second transistor is connected to one terminal of the third transistor.

4. The random access memory of claim 1,
wherein the first transistor is formed in an upper layer,
and the second and third transistors are formed in a lower layer beneath the first transistor.

5. The random access memory of claim 4,
wherein the first transistor includes:
a first gate, a first drain connected to the storage node, a first source connected to a write bit line (WBL), and a first gate contact connecting the first gate to a write word line (WWL);
the second transistor includes:
a second gate, a second drain connected to ground, and a second gate contact connected to the storage node; and
the third transistor includes:
a third gate, a third drain connected to a read bit line (RBL), and a third gate contact connected to a read word line (RWL).

6. The random access memory of claim 4,
wherein the second gate, second drain, third gate, and third drain extend in mutually parallel directions.

7. The random access memory of claim 3,
wherein during a read operation of the random access memory,
the voltages of the write word line (WWL) and the write bit line (WBL) are fixed at 0 so that the first transistor is turned off,
the third transistor of the target random access memory for reading is turned on,
the read bit line (RBL) is precharged to a high-level voltage, and the voltage level of the read bit line (RBL) is adjusted according to the data stored in the storage node,
such that, when a high-level voltage is stored in the storage node, the second transistor is turned on, thereby discharging the read bit line (RBL) through the second and third transistors,
and when a low-level voltage is stored in the storage node, the second transistor is turned off, so that the read bit line (RBL) maintains the high-level precharged state.

8. The random access memory of claim 3,
wherein during a write operation of the random access memory,
the voltages of the read word line (RWL) and the read bit line (RBL) are fixed at 0 so that the third transistor is turned off,
the first transistor of the target random access memory for writing is turned on,
and write data is applied to the write bit line (WBL),
such that, when the write data is high-level data (1), a high-level voltage is stored in the storage node through the first transistor,
and when the write data is low-level data (0), a low-level voltage is stored in the storage node through the first transistor.

9. The random access memory of claim 8,
wherein during a CIM (Computing-In-Memory) operation of the random access memory,
after first data is stored in the storage node through a write operation of the random access memory,
the voltages of the write word line (WWL) and the write bit line (WBL) are fixed at 0 so that the first transistor is turned off,
the read bit line (RBL) is precharged to a high-level voltage,
a high-level voltage or a low-level voltage is applied to the read word line (RWL) of the random access memory targeted for the CIM operation according to second data,
such that, only when both the first data and the second data are high-level data, the second and third transistors are turned on, thereby discharging the read bit line,
and in other cases where the first data and second data are not both high-level, the read bit line is not discharged,
and the MAC operation result of the random access memory cells connected to the read bit line is determined based on the degree to which the read bit line is discharged.

10. The random access memory of claim 9,
wherein the first data is weight data, and the second data is activation data.

11. The random access memory of claim 1,
wherein a driving voltage applied to the gate of the first transistor is greater than a driving voltage applied to the second and third transistors.

12. The random access memory of claim 8,
wherein during a write operation of the random access memory,
a time period during which data is applied to the write bit line (WBL) is set to be longer by a predetermined time than a time period during which a driving voltage (V_{WWL}) applied to the write word line (WWL) to the gate of the first transistor is maintained at a high level.
